(19) United States
(12) Patent Application Publication
(10) Pub. No.: US 2021/0373799 A1
(43) Pub. Date: Dec. 2, 2021

(54) METHOD FOR STORING DATA AND METHOD FOR READING DATA

(71) Applicant: BEIJING BAIDU NETCOM SCIENCE AND TECHNOLOGY CO., LTD., Beijing (CN)

(72) Inventor: Xiaoping YAN, Beijing (CN)

(73) Assignee: BEIJING BAIDU NETCOM SCIENCE AND TECHNOLOGY CO., LTD., Beijing (CN)

(21) Appl. No.: 17/357,579

(22) Filed: Jun. 24, 2021

(30) Foreign Application Priority Data
Oct. 27, 2020 (CN) 202011165682.3

(51) Int. Cl. G06F 3/06

(52) U.S. Cl. CPC G06F 3/0655; G06F 3/0679; G06F 3/064; G06F 3/0604

(57) ABSTRACT

A data storing method includes: obtaining data to be stored and a start address of a currently available storage unit in the storage array, in which the start address comprises a start row, a start column and a start unit identifier; determining a data storage operation to be executed based on the start address and the data to be stored; and controlling a first interface in the storage array to write the data to be stored block by block in the same row into each storage unit of each storage block having the same identifier as the start unit identifier.

### CROSS-REFERENCE TO RELATED APPLICATION

This application is based upon and claims a priority to Chinese Patent Application No. 202011165682.3, filed with the State Intellectual Property Office of P.R. China on Oct. 27, 2020, the entire contents of which are incorporated herein by reference.

### TECHNICAL FIELD

The disclosure relates to the field of artificial intelligence technologies such as data storage and reading, deep learning, and in particular to a data storing method, a data storing apparatus, a data reading method, a data reading apparatus, an electronic device and a storage medium.

### BACKGROUND

With rapid development of artificial intelligence (AI) technologies and more powerful functions of smart devices, AI algorithms based on neural models become more complex, which brings the large computation amount and data storage interaction.

Efficient storage of massive data based on the requirements of neural network has always been a focus of current research. The existing design for a storage-calculation integrated chip has certain limitations. The overall efficiency and flexibility for data storage based on the neural network algorithm characteristics are not very ideal. Therefore, how to improve the storage flexibility and efficiency, in order to better enhance experiences of human-machine interaction, such as the voice interaction, is the key to the current artificial intelligence-related technologies.

### SUMMARY

According to a first aspect of the disclosure, a method for storing data is applied to a storage array including N rows and M columns of storage blocks. Each storage block includes a plurality of storage units, and N and M are positive integers. The method includes: obtaining data to be stored and a start address of a currently available storage unit in the storage array, in which the start address includes a start row, a start column and a start unit identifier; determining a data storage operation to be executed based on the start address and the data to be stored; and controlling a first interface in the storage array to write the data to be stored block by block in the same row into a storage unit of each storage block having the same identifier as the start unit identifier.

According to a second aspect of the disclosure, a method for reading data is applied to a storage array including N rows and M columns of storage blocks. Each storage block includes a plurality of storage units, and N and M are positive integers. The method includes: determining target data to be obtained by a neural network processor unit (NPU), a row address, a column address, and a storage unit identifier of the target data in the storage array, when a data processing ending message sent by the NPU is obtained; determining a data reading operation to be executed based on the row address, the column address and the storage unit identifier of the target data in the storage array; and controlling a third interface in the storage array, to read data simultaneously from each storage unit of each column of storage blocks corresponding to the storage unit identifier based on the row address, the column address and the storage unit identifier and to transmit the read target data to the NPU.

According to a third aspect of the disclosure, an electronic device is applied to a storage array including N rows and M columns of storage blocks. Each storage block includes a plurality of storage units, and N and M are positive integers. The electronic device includes at least one processor and a memory. The memory stores instructions executable by the at least one processor. When the instructions are executed by the at least one processor, the at least one processor is caused to implement the above method for storing data according to the first aspect of the disclosure.

According to a fourth aspect of the disclosure, an electronic device is applied to a storage array including N rows and M columns of storage blocks. Each storage block includes a plurality of storage units, and N and M are positive integers. The electronic device includes at least one processor and a memory. The memory stores instructions executable by the at least one processor. When the instructions are executed by the at least one processor, the at least one processor is caused to implement the above method for reading data according to the second aspect of the disclosure.

It should be understood that the content described in this section is not intended to identify key or important features of the embodiments of the disclosure, nor is intended to limit the scope of the disclosure. Additional features of the disclosure will be easily understood based on the following description.

### BRIEF DESCRIPTION OF THE DRAWINGS

The drawings herein are used to better understand the solution and do not constitute a limitation to the disclosure, in which:

FIG. 1a is a schematic diagram of a storage array according to embodiments of the disclosure.

FIG. 1b is a flowchart of a data storing method according to embodiments of the disclosure.

FIG. 2 is a schematic diagram of determining a start address according to embodiments of the disclosure.

FIG. 3 is a structural schematic diagram of a storage array according to embodiments of the disclosure.

FIG. 4 is a schematic diagram of storage arrays connected and arranged in a voice chip according to embodiments of the disclosure.

FIG. 5 is a block diagram of a storage array according to embodiments of the disclosure.

FIG. 6 is a flowchart of another data storing method according to embodiments of the disclosure.

FIG. 7 is a flowchart of another data storing method according to embodiments of the disclosure.

FIG. 8 is a flowchart of yet another data storing method according to embodiments of the disclosure.

FIG. 9 is a flowchart of a data reading method according to embodiments of the disclosure.

FIG. 10 is a flowchart of determining target data and an address of the target data according to embodiments of the disclosure.

FIG. 11 is a flowchart of another data reading method according to embodiments of the disclosure.

FIG. 12 is a structural schematic diagram of a data storing apparatus according to embodiments of the disclosure.

FIG. 13 is a structural schematic diagram of another data storing apparatus according to embodiments of the disclosure.

FIG. 14 is a structural schematic diagram of a data reading apparatus according to embodiments of the disclosure.

FIG. 15 is a structural schematic diagram of another data reading apparatus according to embodiments of the disclosure.

FIG. 16 is a block diagram of an electronic device used to implement the data storing method or the data reading method according to embodiments of the disclosure.

### DETAILED DESCRIPTION

The following describes the exemplary embodiments of the disclosure with reference to the accompanying drawings, which includes various details of the embodiments of the disclosure to facilitate understanding, which shall be considered merely exemplary. Therefore, those skilled in the art should recognize that various changes and modifications can be made to the embodiments described herein without departing from the scope and spirit of the disclosure. For clarity and conciseness, descriptions of well-known functions and structures are omitted in the following description.

Data processing is a technical process of analyzing and processing data (including numerical and non-numerical data), which includes processing and analyzing various raw data such as analyzing, sorting, calculating and editing. With the increasing popularity of computers, information management that is performed by processing the computer data has become the main application in the field of artificial intelligence technologies. AI is a subject in which computers are used to simulate certain thought processes and intelligent behaviors of people, and both hardware-level technologies and software-level technologies are included. In general, the AI hardware technologies include sensors, dedicated artificial intelligence chips, cloud computing, distributed storage and big data processing. The AI software technologies mainly include computer vision technologies, voice recognition technologies, natural language processing, and machine learning/deep learning, big data processing technologies, knowledge graph technologies and other major directions.

It should be noted that, at present, the main AI technologies still rely on powerful computation and over-storage of the cloud, but the application of AI technologies to the terminals is bound to be the mainstream trend of market demand. A type of smart voice chip has begun to be applied to smart speakers, household appliances control, and modern smart vehicle-mounted system. Smart vehicle-mounted voice chips have broad market prospects, which mainly include voice wake-up and voice recognition based on the terminal, text-to-speech (TTS) broadcasting, and low-latency offline voice interactive control applications. The data for a neural network model that needs to be stored for each voice function is generally several megabytes, tens of megabytes, or even hundreds of megabytes. In actual operations, a large amount of model data needs to be repeatedly loaded for several to tens of times per second, and the resulting ultra-high bandwidth data storage and storage efficiency are one of the core focuses of the new generation of smart voice chips. The efficiency of data storage directly affects the efficiency of data reading, thereby further affecting the experiences of human-machine interaction.

In the related art, internal storage units of the neural network processor unit NPU are generally divided into three storage parts, i.e., independent input data storage, neural network model data (weight data) storage, and output data storage. This technology uses a dedicated method for storing dedicated data, which is not flexible enough. When data quantization difference changes greatly due to accuracy requirements for the neural network model and/or when it requires the input image/audio data frame changes per second, unbalanced data storage is caused, which more or less affects the overall storage efficiency.

Therefore, the embodiments of the disclosure provide a data storing method and a data storing apparatus, and a data reading method and a data reading apparatus. In the embodiments of the disclosure, the various types of data used in the NPU computation are written block by block in the same row into each storage unit of each storage block having the same start unit identifier, and there is no need to set up a dedicated memory for each type of data, thereby avoiding the imbalance of different types of data to affect the overall storage efficiency, and improving storage flexibility. Further, this storing method provides conditions for increasing the bandwidth of the data reading channel, so that a plurality of data channels are adopted for reading a plurality of data simultaneously, which improves reading flexibility.

A data storing method and a data storing apparatus, and a data reading method and a data reading apparatus according to the embodiments of the disclosure are described with reference to the drawings.

The data storing method and the data reading method according to the embodiments are applied to a storage array including N rows and M columns of storage blocks. Each storage block includes a plurality of storage units, and N and M are positive integers. In order to clearly describe the data storing method and the data reading method according to the disclosure, the structure of the storage array according to the disclosure is explained first.

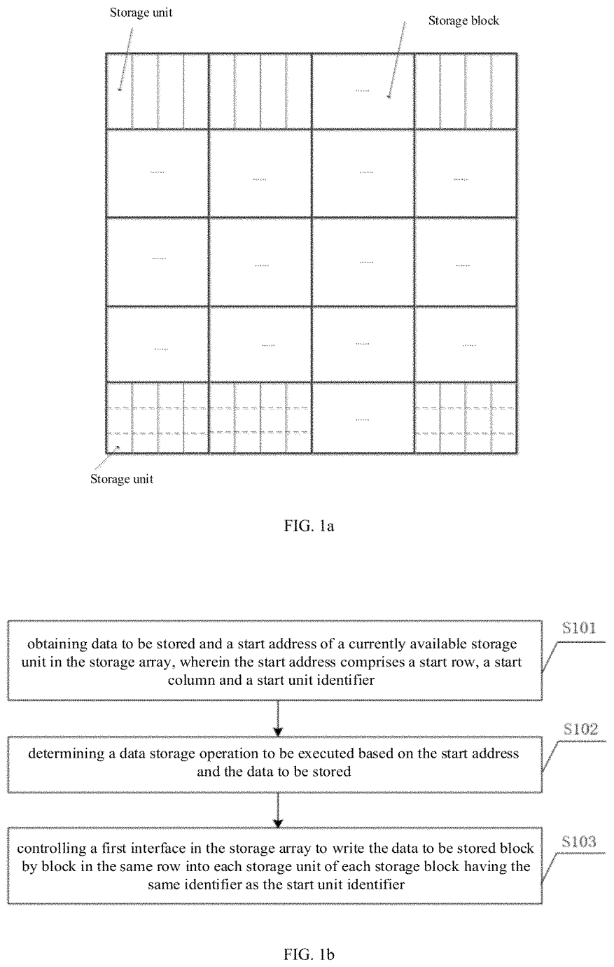

The structure of the storage array according to the disclosure is explained below with reference to FIG. 1a, in which N=5 and M=4 are taken as an example.

As illustrated in FIG. 1a, each storage block in the storage array includes 4 storage units. When storing data, data is stored sequentially in a first storage unit of each storage block in the first row, and the data is stored sequentially in a second storage unit of each storage block in the first row, and so on for the next storage unit of each storage block in the first row, until all the storage blocks in the first row are stored with data. Next, the data is stored sequentially in the first storage unit of each storage block in a second row.

In actual use, the storage units of each storage block may be distributed in a matrix, as shown by the storage block with the dotted lines in FIG. 1a. It may be understood that, when the storage unit of the storage block is arranged as shown in the storage block with the dotted lines in FIG. 1a, in the data storing method, after each storage unit of each block in the first row is fully stored with data in turn, it begins to store the data in each storage unit of the storage block in the second row.

FIG. 1b is a flowchart of a data storing method according to embodiments of the disclosure.

The execution body of the data storing method in the embodiments of the disclosure is a central processing unit (CPU), and the CPU is in a terminal chip or device based on a neural network model.

As illustrated in FIG. 1b, the data storing method includes the following steps.

At block S101, data to be stored and a start address of a currently available storage unit in the storage array are obtained. The start address includes a start row, a start column and a start unit identifier.

Generally, the calculation data of the neural network includes voice data streams and neural network model data (weight data) processed by a digital signal processor (DSP). The neural network model data is mainly stored in a double date rate synchronous dynamic random access memory (referred to as DDR or DDR SDRAM). Due to the limited storage space of the storage array, not all data is stored in the storage array, but only part of the voice data streams and neural network model data are stored in the storage array.

In detail, the CPU monitors data processing progress of the neural network processing unit NPU in real time, and determines the model data that needs to be obtained in time. For example, after the NPU has performed the model calculation for the first 3 layers on time series data to be processed, the CPU may obtain the 4^{th} layer model data, or if the storage space of the storage array is available, the CPU may also obtain the 4^{th} layer model data while the 3^{rd} layer calculation is operated by the NPU. The purpose of obtaining the data to be stored is intended to store the data in the storage array for the NPU's reading. Therefore, it is also necessary to obtain the start address of the storage unit currently available in the storage array. The start address includes the start row, the start column, and the start unit identifier.

At block S102, a data storage operation to be executed is determined based on the start address and the data to be stored.

The storage operation includes the data to be stored and the start address.

At block S103, a first interface in the storage array is controlled to write the data to be stored block by block in the same row into each storage unit of each storage block having the same identifier as the start unit identifier.

The first interface is a data writing interface, an end of the first interface is connected to a standard external system bus, such as including but not limited to AHB/AXI3/AXI4, and the other end is connected to the bus interface control unit of the storage array.

In detail, after the CPU generates the data storage operation, the data storage operation is sent to the first interface in the storage array, so that the first interface writes the data to be stored block by block in the same row into each storage unit of each storage block having the same start unit identifier.

According to the data storing method of the embodiments of the disclosure, the various types of data used in the NPU computation are written block by block in the same row into each storage unit of each storage block having the same start unit identifier, and there is no need to set up a dedicated memory for each type of data, thereby avoiding the imbalance of different types of data to affect the overall storage efficiency, and improving storage flexibility.

It should be noted that, when the start address of the currently available storage unit in the storage array is obtained, there may be no data stored in the storage block where the currently available storage unit is located. At this time, the first storage unit in the currently available storage block is used as a currently available storage unit. Part of the data (not full) may have been stored in the currently available storage block, at this time, when obtaining the start address, the end address of the stored data, that is, the last address of data storage, needs to be taken into consideration.

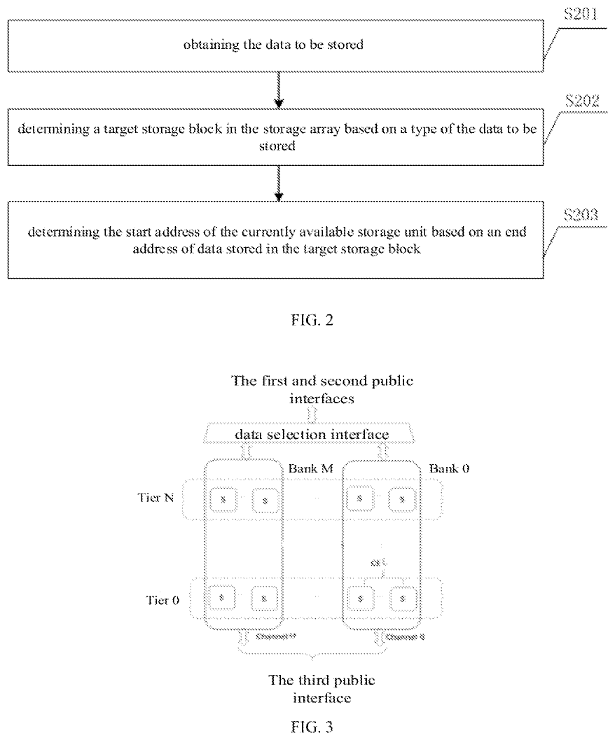

That is, in an embodiment of the disclosure, as illustrated in FIG. 2, block S101 may include the following steps.

At block S201, the data to be stored is obtained.

At block S202, a target storage block in the storage array is determined based on a type of the data to be stored.

The type of data to be stored may be the model data or the time series data to be processed.

The model data and the time series data may be stored in different rows. Generally, the amount of time series data is small. For example, the time series data may be stored in the last row of the storage array. All the remaining rows are used to store the model data of each layer.

At block S203, the start address of the currently available storage unit is determined based on an end address of data stored in the target storage block.

It should be noted that, as illustrated in FIG. 3, the storage array may include N rows (Tier) and M columns (Bank) of storage blocks, and each storage block includes a plurality of storage units S. The end address of the data stored in the target storage block includes the end row, the end column and the end storage unit, and N and M are positive integers.

Each storage unit S may represent a data storage unit.

In the embodiments of the disclosure, DW and AW are used to represent the data width and address width of the storage unit S respectively, and storage capacity of each storage unit S may be represented as 2^{DW}**2^{AW}. CE represents a combined storage (a storage block) that may be composed of L storage units S. Channel represents a number of internal storage channels connected to the NPU, which equals to a number of columns of the storage array. Therefore, a total capacity of the storage array is denoted by C=N*M*L*2^{DW}*2^{AW}/8 bytes, and the storage array may be parameterized to design the size of the storage capacity, that is, by modifying the above parameter design, various types of storage arrays are obtained.

It should be noted that, data may be written in a priority order from the storage unit to the storage column and to the storage row (storage unit→storage column→storage row), starting from the start column, the start row, and the start unit identifier. On the basis, determining the start address of the currently available storage unit is described in the following examples.

In an embodiment of the disclosure, the above block S203 may include: determining that the start row is the next row of the end row, the start column is a first column, the start unit identifier indicates a first storage unit of the first column in the next row of the end row, when the end storage unit is the last storage unit of the end column and the end column is the M^{th} column.

In detail, when the end storage unit of the data stored in the target storage block is the last storage unit in the end column and the end column is the M^{th} column, it means that all the storage units of the end row have stored the data. At this time, the data can only be stored in the next row of the end row. Therefore, when determining the start address, the start row is determined to be the next row of the end row, the start column is determined to be a first column, and the start unit identifier is determined to indicate a first storage unit of the first column in the next row of the end row.

For example, the storage array includes 3 rows and 4 columns, and each storage block includes 3 storage units. If the end row is the first row and the end storage unit is the third storage unit in the fourth column, then the start row is determined to be the second row, the start column is determined to be the first column, and the start unit identifier is determined to indicate the first storage unit of the first column in the second row. When writing data bit by bit, the writing order of the storage units is that: the first storage unit of the first column in the second row to, . . . , to the first storage unit of the fourth column in the second row, to the second storage unit of the first column in the second row, . . . , to the second storage unit of the fourth column in the second row, . . . , until all the data to be stored is written into the storage array.

The block S203 further includes: determining that the start column is the next column of the end column, the start row is the end row, and the start unit identifier is the same as an address of the end storage unit, when the end column is not the M^{th} column.

In detail, in the case where the end column of the data stored in the target storage block is not the last column, it means that there are still storable (available/empty) storage units in the end row. At this time, data may be stored in the empty storage units of the start row. When determining the start address, the start row is determined to be the end row, the start column is determined to be the next column of the end column, and the start unit identifier is the same as the address of the end storage unit.

For example, the storage array includes 3 rows and 4 columns, and each storage block includes 3 storage units. If the end row is the first row and the end column is the second storage unit in the second column, then the start row is determined to be the first row, the start column is determined to be the third column, and the start unit identifier is determined to indicate the second storage unit of the third column in the first row.

That is, in this example, the data is written column by column, unit by unit, then row by row into the storage array. Since each column of the storage array corresponds to a channel, data may be written into each column of the storage array simultaneously, which realizes parallel storage to improve data storage efficiency.

Therefore, based on the end address of the stored data in the target storage block, the start address can be determined effectively and quickly. Furthermore, the data may be written in a column by column and bit by bit to achieve parallel writing, thereby improving data storage efficiency.

Generally, the neural network model data is stored in the DDR. When the model data needs to be stored in the storage array, the model data is stored in the storage array through the first interface. In addition to the model data, the voice data streams need to be stored. If the voice data does not need any processing, the voice data may be directly stored in the storage array through the first interface. If the voice data is preprocessed by the DSP, such as a noise reduction, another writing interface needs to be set up to be responsible for storing the voice data processed by the DSP in the storage array.

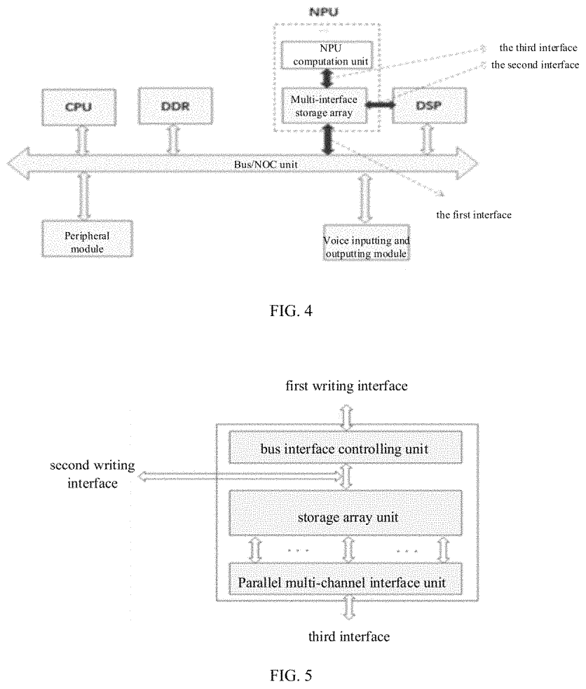

As illustrated in FIG. 4, the storage array includes two interfaces, i.e., the first interface and a second interface. The first interface is the data interface described in the above embodiments, and the second interface is a processor/coprocessor storage interface, such as tightly coupled memory (TCM) and other types of interfaces. The processor includes but is not limited to a CPU/DSP/graphics processing unit (GPU), which is converted into a general static random access memory/first in first out (SRAM/FIFO) interface when connected to the storage array.

When the storage array has a plurality of interfaces, the data storing method may further include: setting a priority of each interface when there are the data to be stored at the plurality of interfaces, based on the type of the data to be stored at each interface of the plurality of interfaces, and writing the data to be stored at a high priority interface into the storage array.

In detail, when there is the data to be stored at the two interfaces, their respective storage addresses may conflict with each other. In order to avoid storage invalidation caused by the conflict, a priority for the two interfaces is set based on the type of the data to be stored at each of the two interfaces, such as the model data and the time series data, so that the corresponding data to be stored at a high priority interface is written into the storage array. It should be noted that if the data storage address at the first interface does not conflict with the data storage address at the second interface, for example, data writing at the first interface and the second interface are performed according to different writing rules, different types of data are then written at the two interfaces simultaneously to further improve storage efficiency.

For example, when the data to be stored at the first interface is the model data and the data to be stored at the second interface is the voice data, the priority of the second interface may be set as higher than that of the first interface, and the data is written firstly through the second interface. In other words, the data is written firstly through the high priority interface.

In the embodiments of the disclosure, the second interface may be directly connected to a TCM data port of the DSP. The transmission efficiency of the processed voice data via the second interface is higher than the transmission efficiency in a traditional standard bus data interaction mode. In addition, the DSP may expand the data space through the second interface, which solves a problem of insufficient data space of the DSP itself. Meanwhile, when a DSP load is not very large, auxiliary calculation of the neural network is performed to increase computation power, and the result data is shared through the second interface.

As illustrated in FIG. 5, the storage array further includes: a third interface (a data reading interface), a bus interface control unit, and a parallel multi-channel storage interface unit.

The third interface is a multi-channel storage interface, which may be an SRAM interface or a FIFO interface, and may be connected to a data bridge/routing switch/computation unit inside the NPU. The bus interface control unit supports standard bus protocol, controls and supports Master and Slave functions. When implementing the Master function, the control unit needs to have DMA storage characteristics. When connecting to the storage array, a general SRAM/FIFO interface adopted is consistent with the second interface. The parallel multi-channel storage interface unit is connected to the storage channels inside the NPU, and each channel has an independent third interface, which achieves parallel data operations simultaneously.

The data storing method of the embodiments of the disclosure is described below with reference to FIGS. 3 to 5.

The current several data frames such as Fn are set, and alternating updates of the data is performed through the first interface and the second interface. The first interface transmits the model data to be stored from the external DDR to the storage array by using the internal DMA data transfer function. The second interface receives the voice data processed by the DSP and transmits the voice data to the storage array. This part of data may be set as Fn+1. These two kinds of interface data may be stored in different rows respectively. Data may be stored in parallel on different rows through the first interface and the second interface, which greatly improves the storage efficiency.

The third interface transmits the current frame Fn of the model data and the voice data to the NPU computation unit simultaneously for related operations. The frame data Fn and Fn+1 may be stored in different rows, which is realized by software control. Therefore, it is ensured that storage operations of the three interfaces are not performed in the same row simultaneously, achieving the effect that the three interfaces may be stored in parallel simultaneously, with the highest overall storage efficiency.

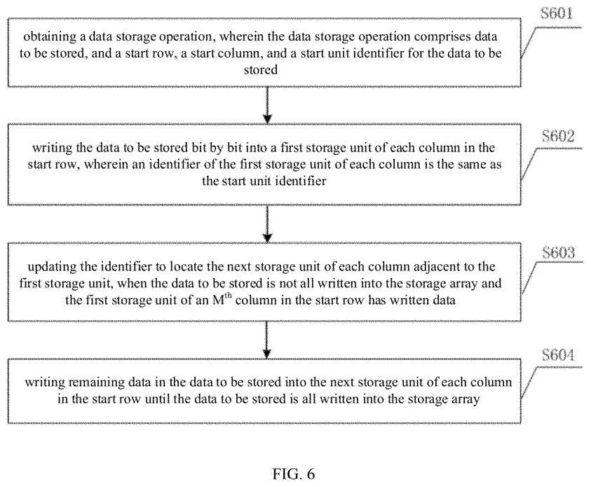

The embodiments of the disclosure provide another method for storing data, FIG. 6 is a flowchart of another data storing method according to embodiments of the disclosure.

The executive body of the method for storing data in the embodiments of the disclosure is the writing interface (i.e., the first interface), and the CPU sends the data storage operation to the writing interface, so that the writing interface stores the data to be stored block by block into the storage array based on the start row, the start column, and the start unit identifier.

The method for storing data in the embodiments of the disclosure is applied to a storage array including N rows and M columns of storage blocks, and each storage block includes a plurality of storage units, and N and M are positive integers.

As illustrated in FIG. 6, the method for storing data includes the following steps.

At block S601, a data storage operation is obtained, the data storage operation includes data to be stored, and a start row, a start column, and a start unit identifier for the data to be stored.

The CPU sends the data storage operation to the writing interface. The data storage operation is generated based on the start address and the data to be stored.

At block S602, the data to be stored is written bit by bit into a first storage unit of each column in the start row, an identifier of the first storage unit of each column is the same as the start unit identifier.

For example, when the start unit identifier indicates the first storage unit, the first storage unit is the first storage unit. When the start unit identifier indicates the second storage unit, the first storage unit is the second storage unit. When the start unit identifier indicates the third storage unit, the first storage unit is the third storage unit.

At block S603, the identifier is updated to locate the next storage unit of each column adjacent to the first storage unit when the data to be stored is not all written into the storage array, and the first storage unit of the M^{th} column in the start row has written data.

At block S604, remaining data in the data to be stored is written bit by bit into the next storage unit of each column in the start row until the data to be stored is all written into the storage array.

For example, the storage array includes 3 rows and 4 columns, and each storage block includes 3 storage units. It is assumed that the start row is the first row, the start column is the third column, and the start unit identifier is the second storage unit of the third column in the first row. After the writing interface writes the data to be stored bit by bit into the second storage unit of each column (from the first to the last column) in the first row, the data storage has not been completed yet. Then, the writing interface continues to write the remaining data into the third storage unit of each column in the first row, until all the data to be stored is written into the storage array.

Therefore, according to the method for storing data of the embodiments of the disclosure, the various types of data used in the NPU computation are written block by block in the same row into each storage unit of each storage block having the same start unit identifier, and there is no need to set up a dedicated memory for each type of data, thereby avoiding the imbalance of different types of data to affect the overall storage efficiency, and improving storage flexibility.

It should be noted that, in the embodiments of the disclosure, when writing data block by block, there is a case where all the storage units in the start row have written data. At this time, it is necessary to change other rows to continue writing data.

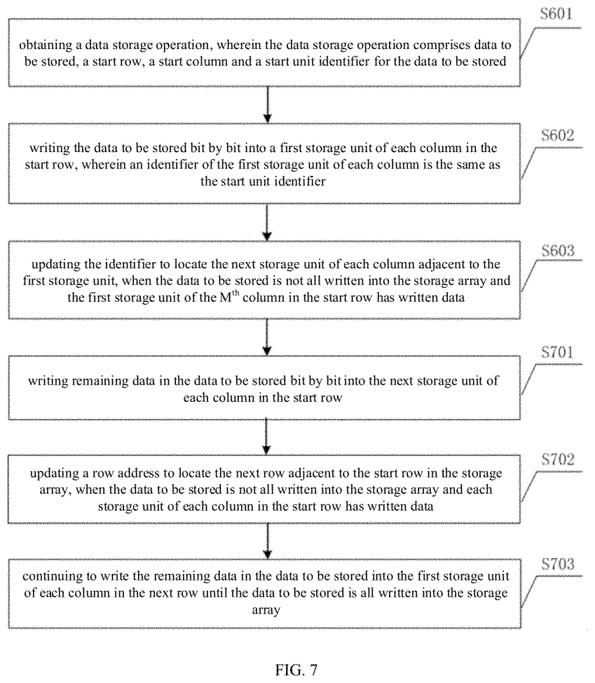

In an embodiment of the disclosure, as illustrated in FIG. 7, block S604 may include the following steps.

At block S701, remaining data in the data to be stored is written bit by bit into the next storage unit of each column in the start row.

At block S702, a row address is updated to locate the next row adjacent to the start row in the storage array when the data to be stored is not all written into the storage array and each storage unit of each column in the start row has written data.

At block S703, the remaining data is continued to write in the data to be stored into the first storage unit of each column in the next row until the data to be stored is all written into the storage array.

For example, after writing the remaining data into the third storage unit of each column in the first row, and the data storage has not been completed yet, the remaining data is continued to write into the first storage unit of each column in the second row until all the data to be stored is written into the storage array.

Therefore, after all the storage units in the start row have written data, a new row is continued to write the data bit by bit, which is beneficial to realize parallel input of data and improve storage flexibility.

It should be noted that the premise that the first/second interface and the third interface may operate at the same time is that the address to be written by the first/second interface is different from the address to be read by the third interface. If the address to be read by the third interface is exactly the address to be written by the first/second interface, then writing data is disabled at this time. After reading the data to be read is completed and the data at this location is no longer in use, then the data is written at this location.

In an embodiment of the disclosure, the data storing method may further include: disabling writing new data to any storage unit when the any storage unit of the storage array is in a data reading state.

For example, if the second storage unit of the first column in the second row is in the data reading state, writing new data to the storage unit is disabled, that is, when the data reading operation conflicts with the writing data operation, the priority of reading data is higher than the priority of writing data.

In this way, a reading/storing disorder phenomenon caused by the conflict between reading data and writing data is avoided, thereby ensuring the effectiveness of data storage and reading.

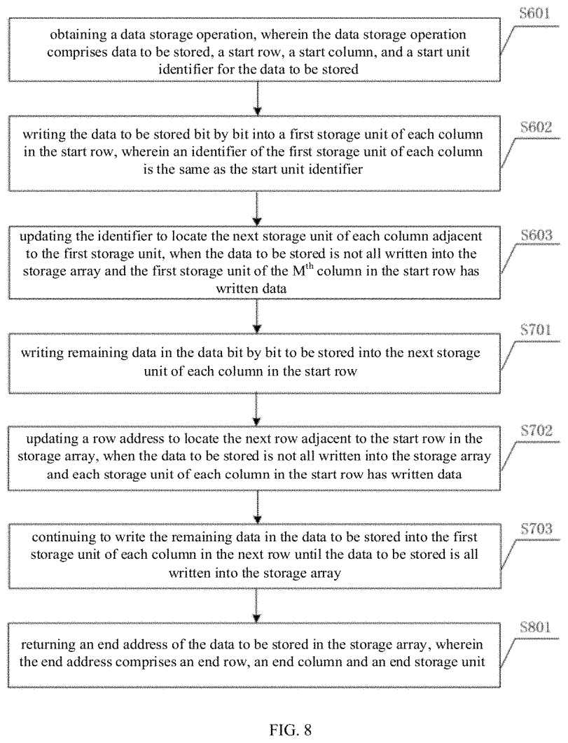

In an embodiment of the disclosure, as illustrated in FIG. 8, after block S703, the method further includes the following step.

At block S801, the end address of the data to be stored in the storage array is returned. The end address includes an end row, an end column and an end storage unit.

In detail, after all the data to be stored is written into the storage array, in order to facilitate the storage of the next data, the writing interface needs to return the end address of the data to be stored in the storage array. The end address includes the end row, the end column, and the end storage unit. The end address is sent to the CPU so that the CPU determines the start address of the available storage unit for the next storage operation based on the end address.

Therefore, after the current data storage is completed, the end address of the data to be stored in the storage array is returned, which facilitates the CPU to quickly and timely determine the start address based on the end address, and further improves the efficiency of storing data.

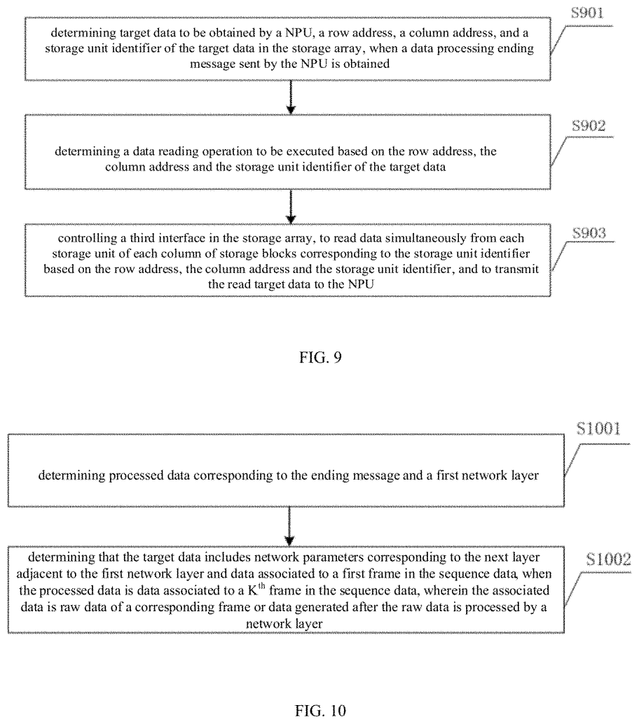

The embodiments of the disclosure provide a data reading method. FIG. 9 is a flowchart of a data reading method according to embodiments of the disclosure.

The execution subject of the data reading method in the embodiments of the disclosure is the CPU. The data reading method is applied to a storage array including N rows and M columns of storage blocks. Each storage block includes a plurality of storage units, and N and M are positive integers.

As illustrated in FIG. 9, the data reading method includes the following steps.

At block S901, target data to be obtained by a neural network processor unit (NPU), a row address, a column address, and a storage unit identifier of the target data in the storage array are determined, when a data processing ending message sent by the NPU is obtained.

In detail, the NPU may send a message indicating the end of data processing (i.e., a data processing ending message) to the CPU after a layer of model parameters are used to process a frame of voice data, and the CPU may determine the target data to be obtained by the NPU and the address of the target data based on the data just processed by the NPU.

For example, when the NPU sends a data processing ending message indicating that a first frame of voice data is processed with the model parameters of the third layer, the target data to be obtained by the NPU is a second frame of voice data. When the NPU sends a data processing ending message indicating that the last frame of voice data is processed with the model parameters of the third layer, the target data to be obtained by the NPU is the model parameters of the fourth layer.

It may be understood that the CPU may record the information about the data obtained by the NPU after every control of the NPU for obtaining data. For example, the information may include which layer of model parameters or which frame of voice data has been obtained.

Furthermore, when the data processing ending message sent by the NPU is obtained, the target data to be obtained is determined based on the recorded information about the data obtained by the NPU.

In addition, since the storage address of each piece of data is generated under the control of the CPU during the data storing process, that is, the storage address of each piece of data is recorded in the CPU, the address of the target data is determined after the target data is determined. At block S902, a data reading operation to be executed currently is determined based on the row address, the column address and the storage unit identifier of the target data in the storage array.

The data reading operation includes the target data to be read, and the start row, the start column, and the start unit identifier of the target data in the storage array.

At block S903, a third interface in the storage array is controlled to read the target data from a first storage unit of each column of storage blocks in the storage array simultaneously and to transmit the read target data to the NPU. The first storage unit has an identifier same as the storage unit identifier of the target data, according to the row address, the column address and the storage unit identifier.

In detail, the CPU generates and sends the data reading operation to the third interface of the storage array. Then the third interface determines a data channel to be activated based on the start row, the start column, and the start unit identifier of the target data in the storage array. The third interface activates the data channel, reads the target data from the first storage unit (having the identifier same as the start unit identifier of the target data) of each column in the start row of the storage array, and transmits the target data to the NPU.

According to the data reading method of the embodiments of the disclosure, data reading is performed in only one storage array based on the start row, the start column and the start unit identifier, and there is no need to set up a dedicated memory for each type of data, thereby avoiding the imbalance of different types of data to affect the overall storage efficiency, and improving storage flexibility.

In the embodiments of the disclosure, sequence data currently processed by the NPU includes K frame data, K being a positive integer. In an embodiment of the disclosure, as illustrated in FIG. 10, at block S901, determining the target data to be obtained currently by the NPU and the row address, the column address, and the storage unit identifier of the target data in the storage array may include the following steps.

At block S1001, processed data corresponding to the ending message and a first network layer are determined.

At block S1002, it is determined that the target data includes network parameters for the next layer adjacent to the first network layer and data associated to a first frame in the sequence data, when the processed data is data associated to a K^{th} frame in the sequence data, in which the associated data may include raw data of the corresponding frame or data generated after the raw data is processed by the network layer.

In detail, the sequence data has a plurality of voice frames, and each frame needs to be processed by each network layer of the model. After each frame is processed, when the processed data is the K^{th} frame data in the sequence data or the data generated after the K^{th} frame data is processed by the network layer, the target data to be read is determined, which includes the network parameters for the next layer adjacent to the first network layer and the data associated to the first frame in the sequence data.

After block S1001, the method may also include: determining data associated to (i+1)^{th} frame as the target data when the processed data is data associated to i^{th} frame in the sequence data, the (i+1)^{th} frame is adjacent to the i^{th} frame, and i is a positive integer and is less than K.

For example, the sequence data has 5 frames. If the processed data is the data associated to the third frame in the sequence data, then the target data is the data associated to the fourth frame.

Therefore, when determining the target data to be read, if the processed data is the data associated to the i^{th} frame in the sequence data, it is determined that the target data is the data associated to the (i+1)^{th} frame. The accuracy of reading data is guaranteed and the reading efficiency is improved.

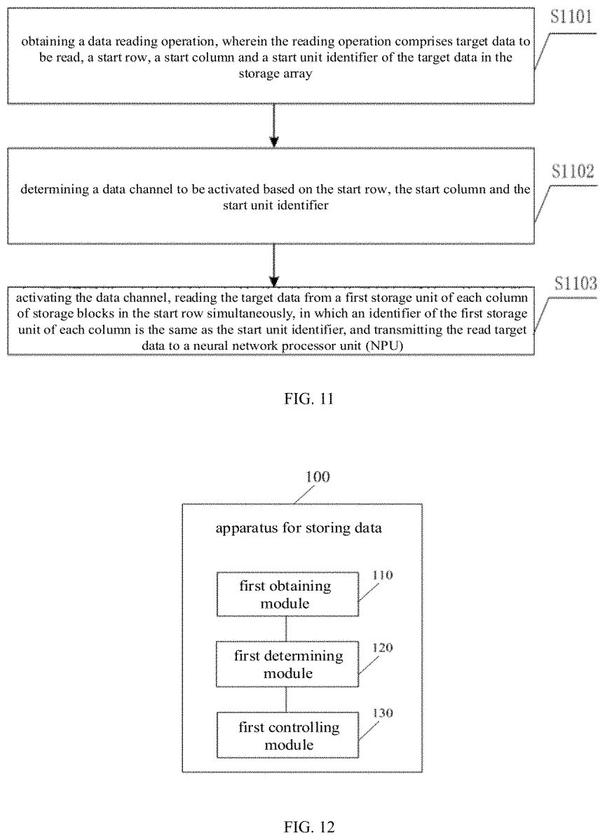

The embodiments of the disclosure provide another data reading method. FIG. 11 is a flowchart of another data reading method according to embodiments of the disclosure.

The execution body of the data reading method is the third interface of the storage array, which is applied to a storage array including N rows and M columns of storage blocks. Each storage block includes a plurality of storage units, and N and M are positive integers.

As illustrated in FIG. 11, the data reading method includes the following steps.

At block S1101, a data reading operation is obtained. The data reading operation includes target data to be read, a start row and a start column, and a start unit identifier of the target data in the storage array.

At block S1102, a data channel to be activated is determined based on the start row, the start column and the start unit identifier.

Each data channel corresponds to a column of the storage array.

At block S1103, the data channel is activated, the target data is read from a first storage unit of each column of storage blocks in the start row of the storage array simultaneously, in which an identifier of the first storage unit of each column is the same as the start unit identifier. The read target data is then transmitted to the NPU.

In detail, after the third interface receives the data reading operation sent by the CPU, the data channel to be activated is determined based on the start row, the start column, and the start unit identifier. Then the data channel is activated. Starting from the start row, the start column and the start unit identifier, the data in the first storage unit indicated by the start unit identifier is read from each column of the storage blocks in the storage array at the same time, and the read data is transmitted to the NPU.

For example, the storage array has 3 rows and 4 columns. If the start row, the start column, and the start unit identifier are the second storage unit of the third column in the second row, the data channels corresponding to the third and fourth columns are activated at the same time.

Thus, according to the start row, the start column, and the start unit identifier, data is read from each corresponding storage unit in the storage array at the same time, and the data is read in parallel, which improves the reading efficiency.

In an embodiment of the disclosure, the block S1102 may include: determining each data channel corresponding to each column as the data channel to be activated when the start column is a first column and a number of storage units occupied by the target data is greater than M.

In detail, when the number of the storage units occupied by the target data is greater than the number of columns of the storage array, the channel corresponding to each column needs to be activated for data reading. Therefore, it is determined that the data channel to be activated is the data channel corresponding to each column.

In an embodiment of the disclosure, the block S1102 may include: determining a j^{th} channel to a M^{th} channel as initial data channels to be activated, and determining a first channel to a (j−1)^{th} channel as supplementary data channels, when the start column is the j^{th} column and the number of storage units occupied by the target data is greater than M-j, in which j is an integer greater than i, and the supplementary data channels are data channels that continue to be activated after reading the target data from the first storage units (whose identifier is the same as the start unit identifier) of the j^{th} to M^{th} columns (from the j^{th} channel to the M^{th} channel) in the start row.

In other words, in the case where the number of storage units occupied by the target data is greater than the number of storable storage units in the start row, it is indicated that a new row is required for continuing to activate the data channels.

For example, the storage array includes 3 rows and 4 columns, and each storage block includes 3 storage units. If the start column is the third column and the number of storage units for the target data is greater than 1, initial data channels to be activated are the third channel and the fourth channel, and the supplementary data channels are the first channel and the second channel.

It should be noted that after reading based on the number of initial channels to be activated, if the target data has not been read completely, the remaining target data continue to be read according to the above reading method until all the target data is read.

Thus, the number of initial channels to be activated is determined based on the start row, the start column, and the start unit identifier of the target data, so as to realize the parallel reading of multiple channels and improve the reading efficiency.

In an embodiment of the disclosure, each storage block includes L storage units, L is a positive integer greater than 1, and the number of storage units occupied by the target data is greater than M.

The action at block S103 may include: reading first data from the first storage unit of each column behind the start column in the start row through the data channel; updating the identifier to locate a next storage unit of each column adjacent to the first storage unit when the start unit identifier is less than L; and continuing to read data from the next storage unit of each column in the start row through the data channel, until all the target data is read.

For example, the storage array includes 3 rows and 4 columns, and each storage block includes 3 storage units. If the number of the storage units occupied by the target data is 5, the first data in the first storage unit in each column behind the start column in the start row is read through the data channel during reading the target data. If the start unit identifier is less than 3, the identifier is then updated, and data is continued to be read from the next storage unit of each column in the start row until all the target data is read.

In an embodiment, after reading the first data from the first storage unit of each column behind the start column in the start row, the method further may include: updating a row address to locate the next row adjacent to the start row when the start unit identifier is L; and continuing to read data from the first storage unit of each column in the next row through the data channel until all the target data is read.

For example, the storage array includes 3 rows and 4 columns, and each storage block includes 3 storage units. If the number of the storage units occupied by the target data is 5, the first data in the first storage unit of each column behind the start column in the start row is read through the data channel during reading the target data. If the start unit identifier is less than 3, the row address is updated, and data is continued to be read from the first storage unit of each column in the next row of the start row until all the target data is read.

In conclusion, the technical solution of the disclosure adopts a coordinated three storage interfaces consistent with high-efficiency storage structure requirements of the NPU model, a matrix storage array and various types of data exchanged by external processors. The first writing interface is configured to update the data from the external DDR. The second writing interface is configured to expand, exchange and share data by the external processor/coprocessor. The third interface is configured for high-speed interaction in parallel of multiple storage channels inside the NPU to the computation unit. Since the matrix storage array is adopted, there is no need to distinguish the input layer, the middle layer, the output layer. The technical solution of the disclosure is different from the data storing method using the dedicated neural network, and makes the storage more flexible and expandable. The storage array is flexible and its parameters are configurable, such as a storage capacity, a storage width and a storage depth at the practical design stage and the number of storage units required for splicing during the design implementation for convenience to the implementation of chip design. At the same time, the storage array has a strong reusability, which may be used in the design of existing NPU or may be applied in the technical fields such as supercomputing that requires high storage efficiency.

Embodiments of the disclosure also provides an apparatus for storing data. FIG. 12 is a schematic diagram of an apparatus for storing data according to embodiments of the disclosure.

As illustrated in FIG. 12, an apparatus 100 for storing data includes: a first obtaining module 110, a first determining module 120 and a first controlling module 130.

The first obtaining module 110 is configured to obtain data to be stored and a start address of a currently available storage unit in the storage array, in which the start address includes a start row, a start column and a start unit identifier. The first determining module 120 is configured to determine a data storage operation to be executed based on the start address and the data to be stored. The first controlling module 130 is configured to control a first interface in the storage array to execute the data storage operation, so that the data to be stored is written block by block in the same row into a storage unit of each storage block having the same identifier as the start unit identifier.

In an embodiment of the disclosure, the first obtaining module 110 is specifically configured to: obtain the data to be stored; determine a target storage block in the storage array based on a type of the data to be stored; and determine the start address of the currently available storage unit based on an end address of data stored in the target storage block.

In an embodiment of the disclosure, the storage array includes N rows and M columns of storage blocks, and each storage block includes a plurality of storage units, and N and M are positive integers. The end address of the data stored in the target storage block includes an end row, an end column and an end storage unit. The first obtaining module 110 is specifically configured to: determine that the start row is the next row of the end row, the start column is a first column, the start unit identifier indicates a first storage unit of the first column in the next row of the end row, when the end storage unit is the last storage unit of the end column and the end column is an M^{th} column.

In an embodiment of the disclosure, the first obtaining module is specifically configured to: determine that the start column is the next column of the end column, the start row is the end row, and the start unit identifier indicates the end storage unit, when the end column is not the M^{th} column.

In an embodiment of the disclosure, the storage array includes a plurality of interfaces, and the apparatus further includes: a setting module, configured to set a interface priority based on the type of the data to be stored at each of the plurality of interfaces when there are the data to be stored on the plurality of interfaces, and write the data to be stored at a high priority interface into the storage array.

It should be noted that other specific implementations of the apparatus for storing data in the embodiments of the disclosure are referred to specific implementations of the data processing method, which are not repeated here.

With the apparatus for storing data according to embodiments of the disclosure, the various types of data used in the NPU computation are written block by block in the same row into each storage unit of each storage block having the same start unit identifier, and there is no need to set up a dedicated memory for each type of data, thereby avoiding the imbalance of different types of data to affect the overall storage efficiency.

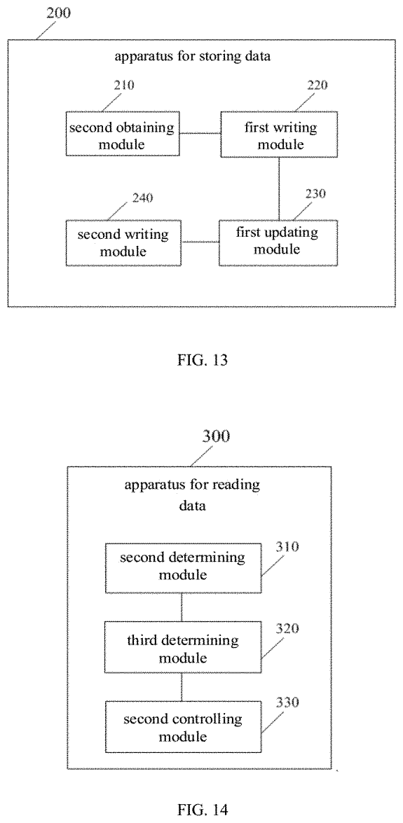

In order to implement the above embodiments, the embodiments of the disclosure also provide another apparatus for storing data. FIG. 13 is a schematic diagram of another apparatus for storing data according to embodiments of the disclosure.

The apparatus is applied to the storage array including N rows and M columns of storage blocks. Each storage block includes a plurality of storage units, and N and M are positive integers.

As illustrated in FIG. 13, an apparatus for storing data 200 includes: a second obtaining module 210, a first writing module 220, a first updating module 230 and a second writing module 240.

The second obtaining module 210 is configured to obtain a data storage operation, in which the data storage operation includes data to be stored, and a start row, a start column, and a start unit identifier for the data to be stored. The first writing module 220 is configured to write the data to be stored bit by bit into a first storage unit of each column in the start row, in which an identifier of the first storage unit of each column is the same as the start unit identifier. The first updating module 230 is configured to update the identifier to locate the next storage unit of each column adjacent to the first storage unit when the data to be stored is not all written into the storage array, and the first storage unit of an M^{th} column in the start row has written data. The second writing module 240 is configured to write remaining data in the data to be stored bit by bit into the next storage unit of each column in the start row until the data to be stored is all written into the storage array.

In an embodiment of the disclosure, the apparatus for storing data includes: a second updating module and a third writing module. The second updating module is configured to update a row address to locate the next row adjacent to the start row in the storage array when the data to be stored is not all written into the storage array and each storage unit of each column in the start row has written data. The third writing module is configured to write the remaining data in the data to be stored into the first storage unit of each column in the next row.

In an embodiment of the disclosure, the apparatus for storing data includes: a disabling module, configured to disable writing new data to any storage unit when the any storage unit of the storage array is in a data reading state.

In an embodiment of the disclosure, the apparatus for storing data includes: a returning module, configured to return the end address of the data to be stored in the storage array, in which the end address includes an end row, an end column and an end storage unit.

It should be noted that the specific implementation of the apparatus for storing data in the embodiments of the disclosure refers to the specific implementation of the data storing method, which is not repeated here.

The apparatus for storing data of the embodiments of the disclosure stores data bit by bit to the storage array based on the start row, the start column, and the start unit identifier, and no dedicated memory for data storage is required, which improves storage flexibility and avoids affecting overall storage efficiency due to imbalance of data storage.

The disclosure further provides an apparatus for reading data, which is applied to the storage array including N rows and M columns of storage blocks. Each storage block includes a plurality of storage units, and N and M are positive integers. FIG. 14 is a schematic diagram of an apparatus for reading data according to embodiments of the disclosure.

As illustrated in FIG. 14, an apparatus for reading data 300 includes: a second determining module 310, a third determining module 320 and a second controlling module 330.

The second determining module 310 is configured to determine target data to be obtained by a neural network processor unit (NPU), a row address, a column address, and a storage unit identifier of the target data in the storage array, when a data processing ending message sent by the NPU is obtained. The third determining module 320 is configured to determine a data reading operation to be executed currently based on the row address, the column address and the storage unit identifier of the target data in the storage array. The second controlling module 330 is configured to control a third interface in the storage array, to read data from a first storage unit (whose identifier is the same as the storage unit identifier of the target data) of each column of storage blocks in the row address of the storage array simultaneously, and to transmit the read target data to the NPU.

In an embodiment of the disclosure, sequence data currently processed by the NPU includes K frame data, K being a positive integer, and the second determining module 310 is specifically configured to: determine processed data corresponding to the ending message and a first network layer; and determine that the target data includes network parameters for the next layer adjacent to the first network layer and data associated to a first frame in the sequence data, when the processed data is data associated to the K^{th} frame in the sequence data, in which the associated data is raw data of the corresponding frame or data generated after the raw data is processed by the network layer.

In an embodiment of the disclosure, the apparatus for reading data includes: a fourth determining module, configured to determine data associated to a (i+1)^{th} frame as the target data when the processed data is data associated to an i^{th} frame in the sequence data, in which the (i+1)^{th} frame is adjacent to the i^{th} frame, and i is a positive integer and is less than K.

It should be noted that the specific implementation of the apparatus for storing data in the embodiments of the disclosure refers to the specific implementation of the data storing method, which is not repeated here.

The apparatus for reading data of the embodiments of the disclosure reads data in only one storage array based on the start row, the start column, and the start unit identifier, and no dedicated memory for reading data is required, which improves reading flexibility and reading efficiency through parallel reading.

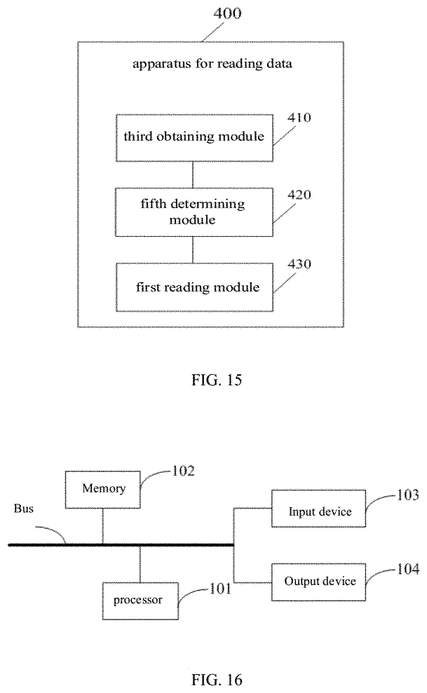

The present disclosure provides another apparatus for reading data, FIG. 15 is a schematic diagram of another apparatus for reading data according to embodiments of the disclosure.

The apparatus for reading data is applied to the storage array including N rows and M columns of storage blocks. Each storage block includes a plurality of storage units, and N and M are positive integers.

As illustrated in FIG. 15, the apparatus for reading data 400 includes: a third obtaining module 410, a fifth determining module 420 and a first reading module 430.

The third obtaining module 410 is configured to obtain a data reading operation, in which the data reading operation includes target data to be read, a start row and a start column, and a start unit identifier of the target data in the storage array. The fifth determining module 420 is configured to determine a data channel to be activated based on the start row, the start column and the start unit identifier. The first reading module 430 is configured to activate the data channel, read the target data from a first storage unit of each column of storage blocks in the start row of the storage array simultaneously, and transmit the read target data to a NPU. An identifier of the first storage unit of each column is the same as the start unit identifier.

In an embodiment of the disclosure, the fifth determining module 420 is specifically configured to: determine each data channel corresponding to each column as the data channel to be activated when the start column is a first column and a number of storage units occupied by the target data is greater than M.

In an embodiment of the disclosure, the fifth determining module 420 is specifically configured to: determine a j^{th} channel to a M^{th} channel as initial data channels to be activated, and determine the first channel to a (j−1)^{th} channel as supplementary data channels, when the start column is the j^{th} column and the number of storage units corresponding to the target data are greater than M−j, j is an integer greater than 1, and the supplementary data channels are channels that continue to be activated after reading data from the first storage units of the j^{th} column to the M^{th} column in the start row.

In an embodiment of the disclosure, each storage block includes L storage units, L is a positive integer greater than 1, a number of storage units occupied by the target data is greater than M, and the first reading module is specifically configured to: read first data from the first storage unit of each column behind the start column in the start row through the data channel; update the identifier to locate the next storage unit of each column adjacent to the first storage unit when the start unit identifier is less than L; and continue to read data from the next storage unit of each column in the start row through the data channel, until all the target data is read.

In an embodiment of the disclosure, the apparatus for reading data includes: a third updating module and a second reading module. The third updating module is configured to update a row address to locate the next row adjacent to the start row when the start unit identifier is L. The second reading module is configured to continue to read data from the first storage unit of each column in the next row through the data channel until all the target data is read.

It should be noted that the specific implementation of the apparatus for storing data in the embodiments of the disclosure refers to the specific implementation of the data storing method, which is not repeated here.

The apparatus for reading data of the embodiments of the disclosure reads data in only one storage array based on the start row, the start column, and the start unit identifier, and no dedicated memory for reading data is required, which improves reading flexibility and reading efficiency through parallel reading.

According to the embodiments of the disclosure, the disclosure provides an electronic device and a readable storage medium for a data storing method or a data reading method, which are described below with reference to FIG. 16.

FIG. 16 is a block diagram of an electronic device used to implement the data storing method or the data reading method according to the embodiments of the disclosure. Electronic devices are intended to represent various forms of digital computers, such as laptop computers, desktop computers, workbenches, personal digital assistants, servers, blade servers, mainframe computers, and other suitable computers. Electronic devices may also represent various forms of mobile devices, such as personal digital processing, cellular phones, smart phones, wearable devices, and other similar computing devices. The components shown here, their connections and relations, and their functions are merely examples, and are not intended to limit the implementation of the disclosure described and/or required herein.

As illustrated in FIG. 16, the electronic device includes: one or more processors 101, a memory 102, and interfaces for connecting various components, including a high-speed interface and a low-speed interface. The various components are interconnected using different buses and can be mounted on a common mainboard or otherwise installed as required. The processor may process instructions executed within the electronic device, including instructions stored in or on the memory to display graphical information of the GUI on an external input/output device such as a display device coupled to the interface. In other embodiments, a plurality of processors and/or buses can be used with a plurality of memories and processors, if desired. Similarly, a plurality of electronic devices can be connected, each providing some of the necessary operations (for example, as a server array, a group of blade servers, or a multiprocessor system). A processor 101 is taken as an example in FIG. 16.

The memory 102 is a non-transitory computer-readable storage medium according to the disclosure. The memory stores instructions executable by at least one processor, so that the at least one processor executes the method according to the disclosure. The non-transitory computer-readable storage medium of the disclosure stores computer instructions, which are used to cause a computer to execute the data storing method or data reading method according to the disclosure.

As a non-transitory computer-readable storage medium, the memory 702 is configured to store non-transitory software programs, non-transitory computer executable programs and modules, such as program instructions/modules (for example, the first obtaining module 110, the first determining module 120 and the first controlling module 130 shown in FIG. 12, or the second obtaining module 210, the first writing module 220, the first updating module 230 and the second writing module 240 shown in FIG. 13) corresponding to the method in the embodiments of the disclosure. The processor 101 executes various functional applications and data processing of the electronic device by running non-transitory software programs, instructions, and modules stored in the memory 102, that is, implementing the data storing method or data reading method in the foregoing method embodiments.

The memory 102 may include a storage program area and a storage data area, where the storage program area may store an operating system and application programs required for at least one function. The storage data area may store data created according to the use of the electronic device for implementing the method. In addition, the memory 102 may include a high-speed random access memory, and a non-transitory memory, such as at least one magnetic disk storage device, a flash memory device, or other non-transitory solid-state storage device. In some embodiments, the memory 102 may optionally include a memory remotely disposed with respect to the processor 101, and these remote memories may be connected to the electronic device for implementing the method through a network. Examples of the above network include, but are not limited to, the Internet, an intranet, a local area network, a mobile communication network, and combinations thereof.

The electronic device used to implement the data storing method or data reading method may further include: an input device 103 and an output device 104. The processor 101, the memory 102, the input device 103, and the output device 104 may be connected through a bus or in other manners. In FIG. 13, the connection through the bus is taken as an example.

The input device 103 may receive inputted numeric or character information, and generate key signal inputs related to user settings and function control of an electronic device for implementing the method, such as a touch screen, a keypad, a mouse, a trackpad, a touchpad, an indication rod, one or more mouse buttons, trackballs, joysticks and other input devices. The output device 104 may include a display device, an auxiliary lighting device (for example, an LED), a haptic feedback device (for example, a vibration motor), and the like. The display device may include, but is not limited to, a liquid crystal display (LCD), a light emitting diode (LED) display, and a plasma display. In some embodiments, the display device may be a touch screen.

Various embodiments of the systems and technologies described herein may be implemented in digital electronic circuit systems, integrated circuit systems, application specific integrated circuits (ASICs), computer hardware, firmware, software, and/or combinations thereof. These various embodiments may be implemented in one or more computer programs, which may be executed and/or interpreted on a programmable system including at least one programmable processor. The programmable processor may be dedicated or general purpose programmable processor that receives data and instructions from a storage system, at least one input device, and at least one output device, and transmits the data and instructions to the storage system, the at least one input device, and the at least one output device.

These computation programs (also known as programs, software, software applications, or code) include machine instructions of a programmable processor and may utilize high-level processes and/or object-oriented programming languages, and/or assembly/machine languages to implement these calculation procedures. As used herein, the terms “machine-readable medium” and “computer-readable medium” refer to any computer program product, device, and/or device used to provide machine instructions and/or data to a programmable processor (for example, magnetic disks, optical disks, memories, programmable logic devices (PLDs), including machine-readable media that receive machine instructions as machine-readable signals. The term “machine-readable signal” refers to any signal used to provide machine instructions and/or data to a programmable processor.

In order to provide interaction with a user, the systems and techniques described herein may be implemented on a computer having a display device (e.g., a Cathode Ray Tube (CRT) or a Liquid Crystal Display (LCD) monitor for displaying information to a user); and a keyboard and pointing device (such as a mouse or trackball) through which the user can provide input to the computer. Other kinds of devices may also be used to provide interaction with the user. For example, the feedback provided to the user may be any form of sensory feedback (e.g., visual feedback, auditory feedback, or haptic feedback), and the input from the user may be received in any form (including acoustic input, voice input, or tactile input).

The systems and technologies described herein can be implemented in a computing system that includes background components (for example, a data server), or a computing system that includes middleware components (for example, an application server), or a computing system that includes front-end components (for example, a user computer with a graphical user interface or a web browser, through which the user can interact with the implementation of the systems and technologies described herein), or include such background components, intermediate computing components, or any combination of front-end components. The components of the system may be interconnected by any form or medium of digital data communication (egg, a communication network). Examples of communication networks include: local area network (LAN), wide area network (WAN), and the Internet.

The computer system may include a client and a server. The client and server are generally remote from each other and interacting through a communication network. The client-server relation is generated by computer programs running on the respective computers and having a client-server relation with each other. The server may be a cloud server, also known as a cloud computing server or a cloud host, which is a host product in the cloud computing service system to solve management difficulty and weak business scalability defects of traditional physical hosts and Virtual Private Server (VPS) services.

According to the technical solution of the embodiments of the disclosure, the various types of data used in the NPU computation are written block by block in the same row into each storage unit of each storage block having the same start unit identifier, there is no need to set up a dedicated memory for each type of data, thereby avoiding imbalance of different types of data that affects overall storage efficiency, and improving storage flexibility. Further, this storing method provides conditions for increasing the bandwidth of the data reading channel, so that a plurality of data channels are adopted for reading data simultaneously, which improves reading flexibility. In the description of the disclosure, the terms “first” and “second” are only used for descriptive purposes, and cannot be understood as indicating or implying relative importance or implicitly indicating a number of indicated technical features. Therefore, the features defined with “first” and “second” may explicitly or implicitly include at least one of the features. In the description of the disclosure, “a plurality of” means at least two, such as two and three, unless specifically defined otherwise.

Although explanatory embodiments have been illustrated and described, it would be appreciated by those skilled in the art that the above embodiments are exemplary and cannot be construed to limit the disclosure, and changes, modifications, alternatives and varieties can be made in the embodiments by those skilled in the art without departing from scope of the present disclosure.

What is claimed is:

1. A method for storing data, which is applied to a storage array comprising N rows and M columns of storage blocks, wherein each storage block comprises a plurality of storage units, and N and M are positive integers, the method comprises:
obtaining data to be stored and a start address of a currently available storage unit in the storage array, wherein the start address comprises a start row, a start column and a start unit identifier;
determining a data storage operation to be executed based on the start address and the data to be stored; and
controlling a first interface in the storage array to write the data to be stored block by block in the same row into a first storage unit of each storage block having the same identifier as the start unit identifier.

2. The method according to claim 1, wherein obtaining the data to be stored and the start address of the currently available storage unit in the storage array comprises:
obtaining the data to be stored;
determining a target storage block in the storage array based on a type of the data to be stored; and
determining the start address of the currently available storage unit based on an end address of data stored in the target storage block.

3. The method according to claim 2, wherein the end address of the data stored in the target storage block comprises an end row, an end column and an end storage unit, and determining the start address of the currently available storage unit, comprises:
determining that the start row is the next row of the end row, the start column is a first column, and the start unit identifier indicates a first storage unit of the first column in the next row of the end row, when the end storage unit is the last storage unit of the end column being an M^{th} column.

4. The method according to claim 3, wherein determining the start address of the currently available storage unit, comprises:
determining that the start column is the next column of the end column, the start row is the end row, and the start unit identifier indicates the end storage unit, when the end column is not the M^{th} column.

5. The method according to claim 1, wherein the storage array comprises a plurality of interfaces, the method further comprises:
setting an interface priority based on the type of the data to be stored at each of the plurality of interfaces when there are the data to be stored at the plurality of interfaces, and writing the data to be stored at a high priority interface into the storage array.

6. The method according to claim 1, further comprising controlling the first interface to:
update the identifier to locate the next storage unit of each column adjacent to a first storage unit, when the data to be stored is not all written into the storage array and the first storage unit of an M^{th} column in the start row has written data; and
write remaining data in the data to be stored bit by bit into the next storage unit of each column in the start row until the data to be stored is all written into the storage array.

7. The method according to claim 6, after writing the remaining data in the data to be stored bit by bit into the next storage unit of each column in the start row, the method further comprises controlling the first interface to:
update a row address to locate the next row adjacent to the start row in the storage array, when the data to be stored is not all written into the storage array and each storage unit of each column in the start row has written data; and
continue to write the remaining data in the data to be stored into the first storage unit of each column in the next row.

8. The method according to claim 6, the method further comprises controlling the first interface to:
disable writing new data to any storage unit when the any storage unit of the storage array is in a data reading state.

9. The method according to claim 6, after writing all the data to be stored into the storage array, the method further comprises controlling the first interface to:
return an end address of the data to be stored in the storage array, wherein the end address comprises an end row, an end column and an end storage unit.

10. A method for reading data, which is applied to a storage array comprising N rows and M columns of storage blocks, wherein each storage block comprises a plurality of storage units, and N and M are positive integers, the method comprises:
determining target data to be obtained by a neural network processor unit (NPU), a row address, a column address, and a storage unit identifier of the target data in the storage array, when a data processing ending message sent by the NPU is obtained;
determining a data reading operation to be executed based on the row address, the column address and the storage unit identifier of the target data in the storage array; and
controlling a third interface in the storage array, to read data simultaneously from each storage unit of each column of storage blocks corresponding to the storage unit identifier based on the row address, the column address and the storage unit identifier, and to transmit the read target data to the NPU.

11. The method according to claim 10, wherein sequence data currently processed by the NPU comprises K frame data, K being a positive integer, and determining the target data to be obtained by the NPU and the row address, the column address, and the storage unit identifier of the target data in the storage array, comprises:
determining processed data corresponding to the ending message and a first network layer; and
determining that the target data includes network parameters corresponding to the next layer adjacent to the first network layer and data associated to a first frame in the sequence data, when the processed data is data associated to a K^{th} frame in the sequence data, wherein the associated data is raw data of a corresponding frame or data generated after the raw data is processed by a network layer.

12. The method according to claim 11, after determining the processed data corresponding to the ending message and the first network layer, further comprising:
determining data associated to a (i+1)^{th} frame as the target data when the processed data is data associated to an i^{th} frame in the sequence data, wherein the (i+1)^{th} frame is adjacent to the i^{th} frame, and i is a positive integer and is less than K.

13. The method according to claim 10, further comprising controlling the third interface to:
determine a data channel to be activated based on the start row, the start column and the start unit identifier; and
activate the data channel, read the target data simultaneously from a first storage unit of each column of storage blocks in the start row, in which an identifier of the first storage unit of each column is the same as the start unit identifier.

14. The method according to claim 13, wherein determining the data channel to be activated based on the start row, the start column and the start unit identifier comprises:
determining each data channel corresponding to each column as the data channel to be activated when the start column is a first column and a number of storage units occupied by the target data is greater than M.

15. The method according to claim 13, wherein determining the data channel to be activated based on the start row, the start column and the start unit identifier, comprises:
determining a j^{th} channel to an M^{th} channel as initial data channels to be activated, and determining a first channel to a (j−1)^{th} channel as supplementary data channels, when the start column is the j^{th} column and a number of storage units occupied by the target data is greater than M−j, wherein j is an integer greater than 1, and the supplementary data channels are data channels that continue to be activated after reading data from the first storage units of the j^{th} column to the M^{th} column in the start row.

16. The method according to claim 13, wherein each storage block comprises L storage units, L is a positive integer greater than 1, a number of storage units occupied by the target data is greater than M, and reading the target data from the first storage unit of each column of storage blocks in the start row simultaneously, comprises:
reading first data from the first storage unit of each column behind the start column in the start row through the data channel;
updating the storage unit identifier to locate a next storage unit of each column adjacent to the first storage unit when the start unit identifier is less than L; and
continuing to read data from the next storage unit of each column in the start row through the data channel, until all the target data is read.

17. The method according to claim 16, after reading the first data from the first storage unit of each column behind the start column in the start row, further comprising controlling the third interface to:
update a row address to locate the next row adjacent to the start row when the start unit identifier is L; and
continue to read data from the first storage unit of each column in the next row through the data channel until all the target data is read.

18. An electronic device, which is applied to a storage array comprising N rows and M columns of storage blocks, wherein each storage block comprises a plurality of storage units, and N and M are positive integers, the electronic device comprises:
at least one processor; and
a memory configured to store instructions executable by the at least one processor;
wherein when the instructions are executed by the at least one processor, the at least one processor is caused to:
obtain data to be stored and a start address of a currently available storage unit in the storage array, wherein the start address comprises a start row, a start column and a start unit identifier;
determine a data storage operation to be executed based on the start address and the data to be stored; and
control a first interface in the storage array to write the data to be stored is written block by block in the same row into a first storage unit of each storage block having the same identifier as the start unit identifier.

19. An electronic device, which is applied to a storage array comprising N rows and M columns of storage blocks, wherein each storage block comprises a plurality of storage units, and N and M are positive integers, the electronic device comprises:
at least one processor; and
a memory configured to store instructions executable by the at least one processor;
wherein when the instructions are executed by the at least one processor, the at least one processor is caused to:
determine target data to be obtained by a neural network processor unit (NPU), a row address, a column address, and a storage unit identifier of the target data in the storage array, when a data processing ending message sent by the NPU is obtained;
determine a data reading operation to be executed based on the row address, the column address and the storage unit identifier of the target data in the storage array; and
control a third interface in the storage array, to read data simultaneously from each storage unit of each column of storage blocks corresponding to the storage unit identifier based on the row address, the column address and the storage unit identifier, and to transmit the read target data to the NPU.
